(19) United States
(12) Patent Application Publication
(10) Pub. No.: US 2009/0056790 A1
(43) Pub. Date: Mar. 5, 2009

(54) Monolithic Mirror Array

(75) Inventors: Jing Tian, Mountain View, CA (US); Peter Young, San Francisco, CA (US); Jason Ellsworth, Mesa, AZ (US); Stephen J. Horne, El Granada, CA (US); Stuart M. Firestone, Danville, CA (US)

Correspondence Address: THE MUELLER LAW OFFICE, P.C., 12951 Harwick Lane, San Diego, CA, 92130, US

(73) Assignee: SOLFOCUS, INC., Mountain View, CA (US)

(21) Appl. No.: 12/263,462

(22) Filed: Nov. 1, 2008

Related U.S. Application Data
(63) Continuation-in-part of application No. 11/138,666, filed on May 26, 2005.
(60) Provisional application No. 60/985,215, filed on Nov. 3, 2007.

(51) Int. Cl. H01L 31/042; G02B 27/10

(52) U.S. Cl. 136/246; 359/619

(57) ABSTRACT

The present invention is an improved solar concentrator array utilizing a monolithic array of primary mirrors fabricated from a single sheet of formable material. The material may include glass, plastic, and metal of a high thermal stability to be able to withstand a broad range of temperature conditions. The monolithic array of this invention may include integral alignment or attachment features for attachment to a supporting structure.

### RELATED APPLICATIONS

This application is a continuation-in-part of the following: (1) U.S. Non-Provisional patent application Ser. No. 11/138,666 filed on May 26, 2005 entitled “Concentrator Solar Photovoltaic Array with Compact Tailored Imaging Power Units”; and (2) U.S. Provisional Patent Application Ser. No. 60/985,215 filed on Nov. 3, 2007 entitled “Monolithic Mirror Array”, all of which are hereby incorporated by reference as if set forth in full in this application for all purposes.

### BACKGROUND OF THE INVENTION

Solar energy generation is an important and growing area in the field of environmentally friendly energy production. Solar concentrators are solar energy generators which increase the efficiency of converting solar energy into electricity. Solar concentrators utilize mirrors and lenses to concentrate light from a relatively large area onto a small photovoltaic cell. For example, the solar cell size in a solar concentrator may be less than 1% of the entry window surface area, rather than having solar cells covering an entire window as in flat panel technology. The cost reduction resulting from the greatly reduced amount of expensive photovoltaic material makes solar concentrators a desirable method of energy production. Moreover, the efficiency of energy conversion is increased due to the highly concentrated light impacting the solar cell. To generate energy at a commercial level, solar concentrators are typically assembled into arrays composed of many individual units. Solar concentrators known in the art utilize, for example, parabolic mirrors and Fresnel lenses for focusing incoming solar energy.

Many factors contribute to the commercial success of solar concentrators, such as manufacturing cost, optical performance, and reliability. Manufacturing cost itself is affected by other aspects, such as material costs, the number of components required for assembly, manufacturing tolerances, and processing efficiencies. Opportunities to make improvements in these various areas are continually being sought in the field of solar energy production. Thus, as the demand for solar concentrator arrays continues to grow, there is a new need to manufacture precision-formed components, especially for those of a relatively large size, at greater volumes and at commercially feasible costs.

### SUMMARY OF THE INVENTION

The invention provides a solid optical component with integral alignment or attachment features formed from a single piece of formable material. The solid optical component may be used as a primary mirror in a concentrated solar energy unit. The present invention also provides a monolithic mirror array of multiple optical components. The optical components of this invention provide for an improved solar energy device by reducing production cost and offering lightweight material options. In accordance with this invention the monolithic array may be made from a single piece of formable material and have a plurality of concave, substantially parabolic mirror surfaces and a plurality of openings at the bases of the concave mirror surfaces. The material may also possess a high melting temperature and a thermal stability that enables the optical components to function at temperatures between about −40 and +200° C. Alignment or attachment features that are integral with the optical components enable high-precision connections between the optical components and a supporting structure, such as a backpan or other optical components. Monolithic arrays of optical components may be formed from a single sheet of a formable material using a thermal forming or an injection molding process. The shape of the monolithic array may be supplemented by stiffening features formed from the single sheet of plastic, fiberglass, metal or glass. The invention provides an array of optical components to be monolithically fabricated as primary mirrors for a solar concentrator array.

### BRIEF DESCRIPTION OF THE DRAWINGS

FIG. 1A depicts a cross section of an exemplary mirror of the present invention. FIG. 1B is a perspective view of an exemplary mirror with attachment features. FIG. 1C is a perspective view of an exemplary mirror with alignment features.

FIG. 2 is an exploded view of an exemplary solar power unit of this invention.

FIG. 3A shows a top perspective view of a linear monolithic array of primary mirrors. FIG. 3B is a top perspective view of a monolithic array of mirrors with sidewalls. FIG. 3C is a bottom perspective view of a monolithic array of primary with integral attachment components.

FIG. 4A provides a perspective view of an exemplary array comprised of multiple monolithic arrays. FIG. 4B provides a perspective view of an exemplary single planar monolithic array including rows and columns of concave optical components.

FIG. 5 depicts an exploded perspective view of an exemplary solar energy system of this invention.

### DETAILED DESCRIPTION OF THE EMBODIMENTS

Reference now will be made in detail to embodiments of the disclosed invention, one or more examples of which are illustrated in the accompanying drawings.

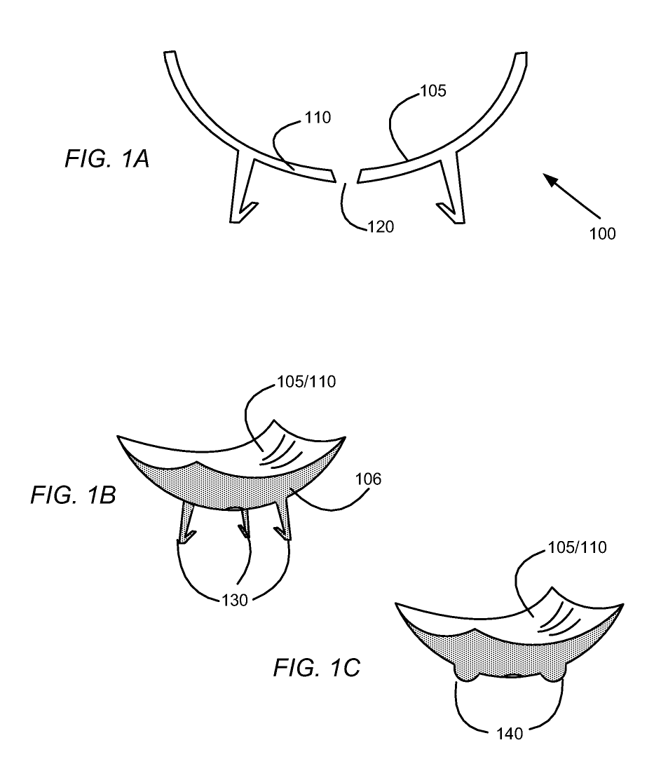

FIG. 1A illustrates a solid optical component 100 according an embodiment of this invention. The optical component 100 includes a curved solid body 110, a reflective concave mirror surface 105 and an aperture 120 at the base of the curved body 110. In one embodiment, the concave surface 105 may be substantially parabolic in shape. The optical component 100 may be made of any formable material that maintains shape and stiffness over a broad range of temperatures. For solar applications, the material is chosen to be stable at the typical working temperatures of a concentrated solar energy system. In one embodiment, the formable material may have high thermal stability over a working temperature range from about −20 to about +150° C. In another embodiment the solid optical component may withstand a working temperature range of about −40 to 200° C. The material may be plastic (e.g., polycarbonate, polyamide, polyetherimide, polyphenylene sulfide, polyethersulfone, polyetheretherketone, etc.), glass (e.g., soda lime, borosilicate, etc.) or metal (e.g., silver, aluminum, etc.). Furthermore, the formable material may be any combination of these materials (e.g., fiberglass) to improve the mechanical properties, such as stiffness or strength, or to reduce the weight of the solid optical component 100. In one embodiment, the formable material may be a laminate such as graphite/epoxy. In another embodiment the formable material may be plastic optionally mixed with a filler material such as glass beads, carbon fibers, and the like to improve the thermal properties of the solid optical component 100.

In one embodiment, the formable material may be a thermoset plastic which may include polymer materials that irreversibly cure to a form. The cure may be done through heat (e.g., above 200° C.), through a chemical reaction (two-part epoxy, for example), or irradiation such as electron beam processing. Thermoset materials are usually liquid or malleable prior to curing and designed to be molded into their final form. The curing process transforms the thermoset plastic resin into a plastic or rubber by a cross-linking process. Energy and/or catalysts may be added to cause the molecular chains to react at chemically active sites (unsaturated or epoxy sites, for example), linking into a rigid, 3-D structure. The cross-linking process forms a molecule with a larger molecular weight, resulting in a material with a higher melting point or transition temperature. During the reaction, the molecular weight increases to a point so that the melting point is higher than the surrounding ambient temperature, and the material forms into a solid material.

One aspect of the curved optical component includes the precise curvature of the concave surface. The material may be precisely shaped into a substantially hyperbolic curved optical component by any means compatible with the properties of the formable material. For example, a precision glass curved surface may be formed by vacuum slumping. A metal curved optical component may be formed by any method known in the art for forming metal shapes (e.g., stamping, forming, metal injection molding, sintering, casting, etc.). A formable material that includes a thermoset plastic may be shaped by thermal forming, such as vacuum thermal forming or injection molding.

Injection molding is well known in the art as a method for forming shaped bodies from a formable material. The process includes feeding a resin to an injection molding machine through a hopper. The resin enters the injection barrel by gravity though the feed throat. Upon entrance into the barrel, the resin is heated to the appropriate melting temperature. The resin is injected into the mold by a reciprocating screw or a ram injector. The mold is the part of the machine that receives the plastic and shapes it appropriately. The mold may form specific features of the optical component (e.g., curvature, aperture shape, perimeter shape, alignment and attachment features). The mold may be cooled constantly to a temperature that allows the resin to solidify and be cool to the touch. The mold plates may be held together by hydraulic or mechanical force. In one embodiment of this invention a solid optical component may be made with a mold that forms the shape, curvature, aperture, and alignment features of a primary mirror for a solar energy unit. In a particular embodiment, no further post-processing is needed to shape the solid optical component. One aspect of this embodiment is a reduced manufacturing cost as post-processing steps are eliminated.

Vacuum thermal forming provides an alternative method for forming shaped bodies from a formable material. The process involves forming thermoplastic sheets into three-dimensional shapes through the application of heat and pressure. In general, vacuum thermal forming refers to all sheet forming methods. During the vacuum thermal forming processes, a formable material is heated until it becomes pliable, and then it is placed over a mold and drawn in by a vacuum, gravity, centrifugal force, and/or pressure on the reverse side until it takes on the desired shape. Vacuum thermoforming provides a method for producing a monolithic optical component with sharp integral formed details or features. An advantage to vacuum forming is that it involves fewer parts and tooling than injection molding. Some features, such as the curvature of the concave body and the integral attachment means, may be formed by the mold during thermal forming, while others, such as the central aperture, may be formed by post processing steps such as laser cutting.

A single piece of formable material may be shaped into an optical component that includes additional integral features formed from the piece of material. FIG. 1B depicts one embodiment of an optical component of this invention that has an attachment means 130 as an integral part of the curved body 110. The attachment means 130 may be disposed on the underside 106 of the concave surface 105 as depicted, or may be located in other areas such as on an edge of the curved body 110. In one embodiment, the attachment means 130 may be a hook or bayonet clip for attaching to a supporting structure such as a backpan. The curved body 110 may be integrated with one or more attachment means 130. In one embodiment, the formable material may be shaped by insert molding around either the alignment or attachment means (e.g. molding plastic around a pre-made clip, hook, nub or other alignment or attachment feature).

FIG. 1C depicts another embodiment of the present invention in which alignment features 140 are an integral part of the curved body 110. A curved optical component may be integrated with one or more alignment features 140. The alignment features 140 may be nubs or grooves or any means that may be used to align the optical component to a specific location on a supporting structure such as a backpan. The alignments features 140 may match or align with features on a supporting structure to orient the optical component within the supporting structure. In one embodiment, the alignment or attachment features may be used to orient or connect separate optical components to one another to form an array of optical components. The features may include alignment pins with holes/slots, ball and socket joints, bayonet fittings (turn and snap), dovetail joints, cup and cone features (taper fit), or any other feature known in the art for connecting components.

A reflective coating may be applied to the concave surface 105 of the optical component after shaping. In some embodiments, the coating is silver or aluminum, but may also be other reflective materials known in the art. The mirroring may occur by any means known in the art that is compatible with the formable material used for the curved solid body surface. In one embodiment the reflective coating may be applied by physical or chemical vapor deposition (PVD, CVD). Other operable processes for applying the coating include, for example, electroless deposition or in-mold decoration (IMD). The mirroring process may include the deposition of additional layers to improve the adhesion and to protect the reflective coating of the concave surface 105.

The curved solid body of this invention may be any shape compatible with an optical component for a solar energy system. In one embodiment the concave surface 105 of the curved body 110 may be substantially parabolic in shape. The perimeter of the curved body 110 may be substantially square or hexagonal, or any other shape, such as triangular or round, etc. The opening (aperture 120) at the base of the curved form may be any size and may be modified to facilitate mounting of additional components. For example, the aperture 120 may be fluted, threaded, or include a key hole to align or mount additional components of a solar energy system, such as a receiver package.

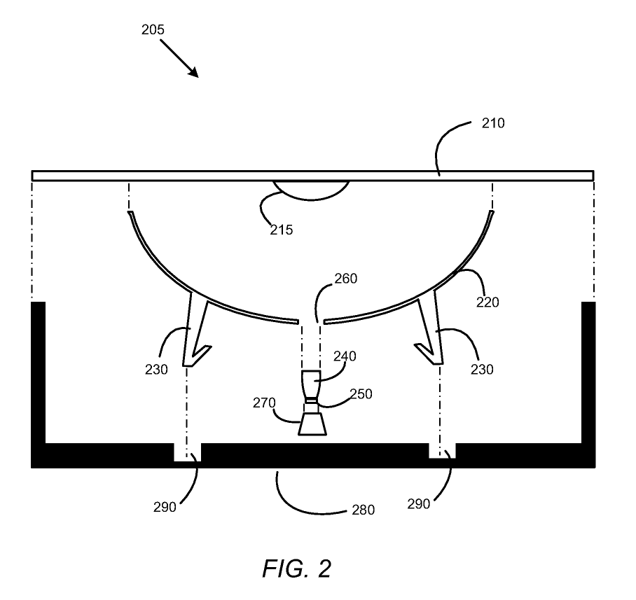

In one embodiment of this invention, a solar power energy unit may be formed from the curved optical component of this invention. A curved solar energy unit has been described in co-pending U.S. patent application Ser. No. 11/138,666 entitled “Concentrator Solar Photovoltaic Array with Compact Tailored Imaging Power Units” which is hereby incorporated by reference in its entirety. More specifically the noted application describes a set of mirrors, a rod, and spatial relationships and alignment means for these components. FIG. 2 shows a simplified exploded cross-sectional illustration of an individual power unit 205, which includes a protective front panel 210, a solid curved optical component as a primary mirror 220, a secondary mirror 215, a non-imaging concentrator 240 located at the opening 260 at the base of primary mirror 220 and a protective backpan 280. A non-imaging concentrator 240 delivers solar radiation to a photovoltaic PV solar cell 250 for conversion to electricity. The non-imaging rod 240 and PV cell 250 may be disposed in a receiver device 270, which may fit integrally into the opening 260. In one embodiment, the fit may include a hermetic seal. Alternatively, opening 260 may be omitted from primary mirror 220, and the receiver device 270 may mounted directly onto the concave surface of primary mirror 220. The curved optical primary mirror 220 may be attached to or aligned within a supporting structure such as a backpan 280. The curved optical primary mirror 220 may be attached or aligned with other curved optical primary mirrors via integral attachment or alignment features 230 on one or more of the mirrors. The backpan may have attachment or alignment features 290 such as grooves, detents, cantilevered snaps, alignment pins and holes/slots, ball and socket joints, bayonet fittings (turn and snap), dovetail joints, cup and cone features (taper fit), adhesive, or spring mounting devices etc., to facilitate the attachment or alignment with the solar power energy unit via attachment/alignment features 230.

It can be understood from FIG. 2 that construction of an array of solar concentrator power units may involve numerous manufacturing steps. The components within each individual power unit 205 are assembled and aligned, and then the discrete power units may be assembled and aligned into a complete array in which a plurality of solar concentrator power units are arranged onto a supporting structure. The alignment of an array of power units must be precise with respect to the orientation of the mirrors in order to insure maximum conversion of solar energy into electrical energy. In one embodiment of the present invention, the mounting and alignment of the power units to a supporting structure or to other power units is improved by integral alignment or mounting features on the solid optical component. The attachment may be by means of screws, locks, alignment pins and holes/slots, ball and socket joints, bayonet fittings (turn and snap), dovetail joints, cup and cone features (taper fit), nuts and bolts, rivets, heat staking, welding, or adhesives such as glue, solder, epoxy, brazing, or hot melt polyurethane, etc.

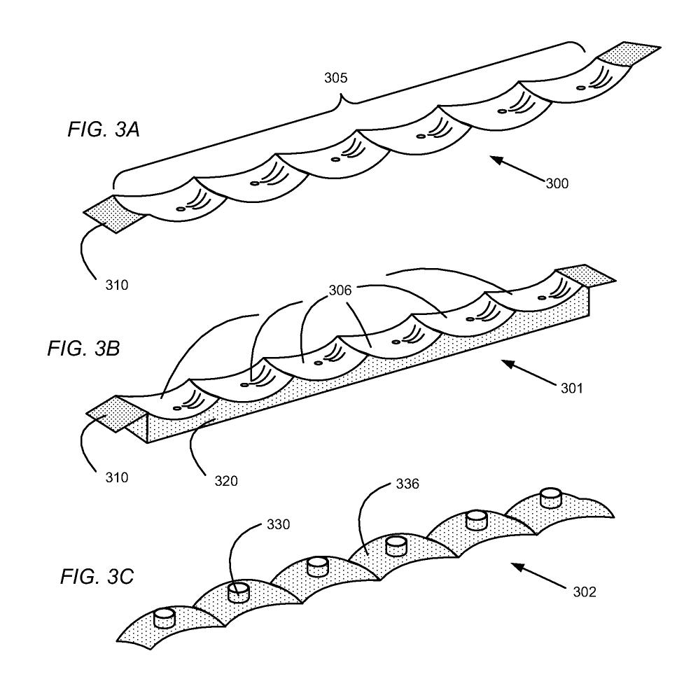

Mirror manufacturing costs as well as array assembly costs may be dramatically reduced by replacing discrete optical components (e.g., primary mirror 220 of FIG. 2) with a monolithic mirror array. FIGS. 3A, 3B, and 3C are drawings of various embodiments of the present invention, in which a monolithic array of primary mirrors is formed from a single sheet of a formable material such as plastic, glass, or metal as described previously for a single solid optical component. FIG. 3A is a perspective view of a monolithic array 300 composed of a strip of six primary mirrors 305 arranged in a row. It is understood that any number of primary mirrors may be included in this array. The monolithic array of this invention may include a reflective surface 306 on the concave surfaces of the array. Combining multiple mirrors in a single piece of material is beneficial in reducing manufacturing costs by reducing the number of parts in a solar energy system and improving the alignment between individual mirrors. A single monolithic array of multiple optical components is also advantageous because the process of applying a reflective surface to a single sheet of material is more effective than applying a reflective surface to multiple components.

The monolithic array 300 may be made from any formable material such as glass, metal or plastic that may withstand a broad range of environmental conditions (e.g., temperature, humidity, light intensity, shocks and vibrations) while retaining shape and stiffness. The formable material may be shaped into an array by any means used to shape a single curved optical component. For example, a plastic monolithic array may be formed by injection molding, thermal forming or any other method known in the art for shaping a formable material. Plastic may offer an advantage of being lighter in weight, or possess improved thermal resistance or offer lower costs over other materials. In one embodiment the monolithic array may be plastic formed by injection molding. A glass monolithic array may be formed by vacuum slumping. A metal monolithic array may be formed by stamping, forming, metal injection molding, sintering, casting, etc.

A monolithic array of curved optical components of this invention may possess the same features that a single curved optical component of this invention may possess. In addition, the array of optical components of this invention may include an integral overhanging edge 310 around any portion of the array as shown in FIG. 3A. The overhanging edge 310 may be used to align or attach the monolithic array 300 to a supporting structure (e.g., a backpan, tracking device, open frame etc.). The edge 310 may be planar, curved, or adapted (e.g., to form a clip) in order to accommodate attachment or alignment to a supporting structure. In one embodiment, the overhanging edge 310 may be used to connect a plurality of monolithic arrays to one another as well as to a supporting structure.

The multiple concave surfaces of the array may be substantially parabolic in shape and may each include an opening at the base for integrally mounting additional components. The monolithic array may be intrinsically rigid and maintain a rigid planar arrangement using the intrinsic mechanical strength of the formable material. In one embodiment the monolithic array may include stiffening features such as integral side walls or columns that offer improved mechanical strength and rigidity. One embodiment of a monolithic array 301 with improved rigidity can be seen in FIG. 3B, in which sidewalls 320 are incorporated to provide increased strength and rigidity along the long axis of the array. In a further embodiment, a monolithic array may have intrinsic features which assist in the alignment or attachment to a supporting structure (e.g., a backpan, tracking device, open frame etc.). An example of one embodiment of a monolithic array with attachment features can be seen in FIG. 3C. In this bottom perspective view, the underside 336 of a monolithic array 302 is shown with optional attachment features 330 on the bases of the concave surfaces. These attachment features 330 are depicted in this embodiment as cylindrical extensions and may be integral parts of the formable material used in the monolithic array 302. In one embodiment, the features 330 may be attachment components for mounting the array onto a supporting structure. The attachment features 330 may also serve to align and orient the monolithic array 302 in a supporting structure. The attachment features 330 may be placed on any fraction of the mirrors in the monolithic array 302.

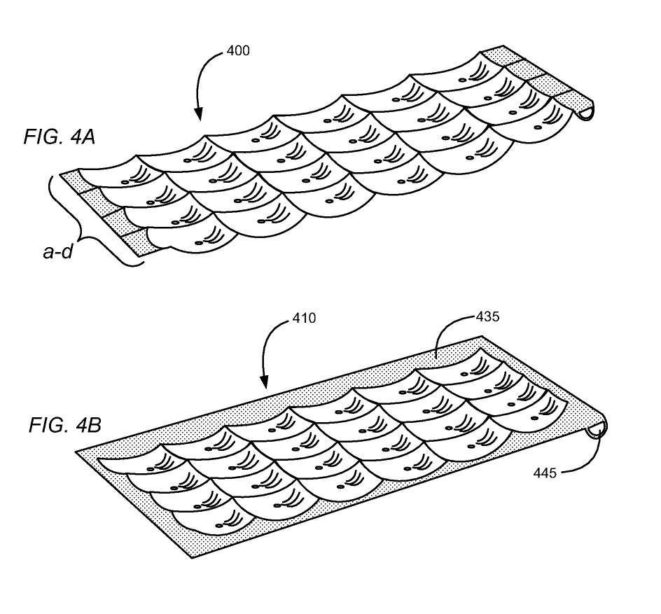

FIGS. 4A and 4B depict larger arrays of optical components. In one embodiment of this invention, multiple strips of arrays of optical components may be combined to form a larger array. For example, FIG. 4A depicts a larger array 400 comprised of four monolithic strips of optical components (a-d). While the optical components are shown as having square perimeters, they may have other shapes such as hexagonal or circular or any combination. A square or hexagonally shaped perimeter offers a variety of arrangements for assembling the plurality of optical components in an efficient manner. Forming a monolithic array allows for multiple primary mirrors to be formed simultaneously, reducing the number of components and inherently aligning them properly with respect to each other. Multiple monolithic arrays arranged in a larger array may be of any configuration and comprise any configuration of optical components. For example, an array of concave surfaces that have substantially square perimeters may be joined to an array of concave surfaces that have substantially circular perimeters. Two or more monolithic arrays may be secured to each other at multiple locations, or continuously in the case of a sealed concentrating solar energy system, in order to secure and maintain alignment of the arrays. Arrays may be joined by various means such as adhesive (e.g., fritting, welding, and glues) or mechanical (e.g., clips, screws, snaps) means. In one embodiment metal monolithic arrays may be joined by welding. In another embodiment, glass monolithic arrays may be joined by glass fritting. In still another embodiment plastic arrays may be joined by an adhesive medium.

Rather than joining multiple small arrays into a larger array, a larger array 410 comprising two or more rows of concave surfaces may also be fabricated from a single sheet of formable material as seen in FIG. 4B. In one embodiment, the edge of the monolithic array 410 may form an overhanging surface 435. The overhanging surface 435 may be shaped to form an attachment feature 445, depicted here as a tubular clip. The attachment feature 445 may serve to connect the monolithic array 410 to a supporting structure. The monolithic array may be any size, as limited by practical handling and forming equipment, as well as considerations of the formable material. In an exemplary embodiment, the size of the array may be on the order of 1.2 meters by 1.4 meters.

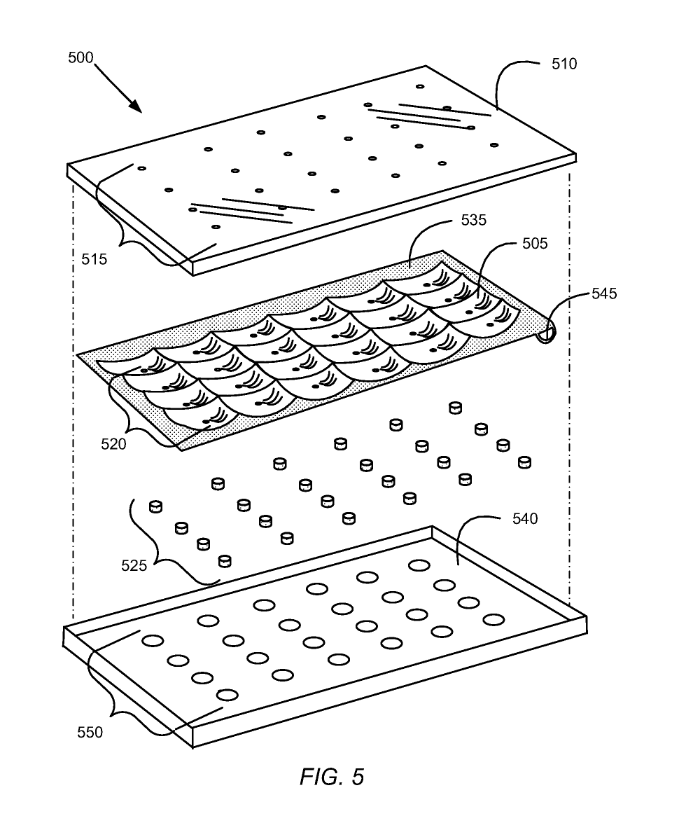

In one embodiment of this invention, one or more monolithic arrays of optical components may provide an array of primary mirrors in a concentrating solar energy system. FIG. 5 provides an exploded perspective view of an exemplary solar concentrator array 500 of this invention. Array 500 is comprised of a monolithic array of primary mirrors 505 with central openings 520, and an array of receiver assemblies 525. The receiver assemblies 525 may incorporate solar cells, optional non-imaging concentrators and an electrical system (not shown). A front panel 510 with attached secondary mirrors 515 may be disposed on the surface of the array of primary mirrors. An optional backpan 540 may be used to provide support and protection for the monolithic array of solar concentrator units, as well as to provide heat dissipation. The backpan 540 may also contain alignment or attachment features 550 that combine with alignment or attachment features (not shown) on the monolithic array. Thus the primary mirrors 505 in the array may be inexpensively and efficiently aligned to provide maximum uniformity of orientation. In the operation of this embodiment, solar radiation enters solar concentrator unit 500 through front panel 510 and reflects off of primary mirror 505 to secondary mirror 515. Secondary mirror 515, which is located in a position defining a focal region of the primary mirror 505, then reflects the radiation to a non-imaging concentrator mounted in the receiver assembly 525 which transmits the light to a solar cell for conversion to electrical energy. In one embodiment the monolithic array of primary mirrors, the receiver elements and the front panel with secondary mirrors may be hermetically joined to each other to form a hermetically sealed and enclosed solar energy device.

The monolithic arrays of the present invention provide pre-aligned optical components with integral precision alignment features to enable quick passive alignment and assembly of a monolithic primary mirror array into a solar energy device. By utilizing a monolithic array, the process of handling, manipulating, and affixing mirrors to a CPV or lighting unit is greatly simplified and cost is reduced. Furthermore, the cost of the mirror production is greatly reduced as precision fixturing and processing can be done on multiple mirrors at one time rather than on individual mirrors. The precision-formed monolithic mirror arrays provide precise mirror-to-mirror positioning in the X, Y, and Z axes, thereby allowing for more efficient panel-level alignment in comparison to discrete mirrors.

While the specification has been described in detail with respect to specific embodiments of the invention, it will be appreciated that those skilled in the art, upon attaining an understanding of the foregoing, may readily conceive of alterations to, variations of, and equivalents to these embodiments. These and other modifications and variations to the present invention may be practiced by those of ordinary skill in the art, without departing from the spirit and scope of the present invention, which is more particularly set forth in the appended claims. Furthermore, those of ordinary skill in the art will appreciate that the foregoing description is by way of example only, and is not intended to limit the invention. Thus, it is intended that the present subject matter covers such modifications and variations as come within the scope of the appended claims and their equivalents.

What is claimed is:

1. A monolithic mirror array comprising:
a single piece of formable material having a first side and a second side;
a plurality of concave surfaces formed in the first side, wherein each of the concave surfaces is substantially parabolic in shape and has a base, and wherein an aperture is located at each base;
a mirror coating deposited on at least a portion of the concave surfaces of the first side; and
a plurality of alignment elements integral to the formable material.

2. The monolithic mirror array of claim 1, wherein the plurality of concave surfaces is arranged in a linear array.

3. The monolithic mirror array of claim 1, wherein the plurality of concave surfaces is arranged in a planar array.

4. The monolithic mirror array of claim 1, wherein the formable material forms a rigid planar structure.

5. The monolithic mirror array of claim 1, wherein the formable material is metal.

6. The monolithic mirror array of claim 1, wherein the formable material is plastic.

7. The monolithic mirror array of claim 1, wherein the formable material is glass.

8. The monolithic mirror array of claim 1, wherein the formable material further comprises a filler material.

9. The monolithic mirror array of claim 1, wherein a portion of the concave surfaces has a substantially hexagonal perimeter.

10. The monolithic mirror array of claim 1, wherein a portion of the concave surfaces has a substantially square shaped perimeter.

11. A solar energy system comprising:
a monolithic mirror array comprising: a formable material having a first side and a second side; a plurality of concave surfaces formed in the first side, wherein each of the concave surfaces is substantially parabolic in shape and has a base, and wherein an aperture is located at each base; and a mirror coating deposited on at least a portion of the concave surfaces of the first side;
a plurality of receiver devices, each comprising a non-imaging rod and a photovoltaic cell;
a transparent planar surface disposed on the first side of the monolithic mirror array; and
a plurality of convex secondary mirrors mounted to the planar surface, wherein the convex secondary mirrors are located in a position defining a focal region at which light received by the concave surfaces is concentrated onto the photovoltaic cells.

12. The solar energy system of claim 11, wherein the monolithic mirror array remains stable within a temperature range of −40 to +200° C.

13. The solar energy system of claim 11, wherein the monolithic mirror array further comprises a plurality of alignment elements integral to the formable material.

14. The solar energy system of claim 11, wherein the monolithic mirror array further comprises an integral attachment element.

15. The solar energy system of claim 14, wherein the attachment element comprises a locking clip disposed on the second side of the monolithic mirror array.

16. The solar energy system of claim 14, wherein the attachment element comprises a tubular clip disposed on an edge of the monolithic mirror array.

17. The solar energy system of claim 13, wherein the alignment elements comprise a plurality of protruding nubs disposed on the second side of the monolithic mirror array.

18. The solar energy system of claim 11, further comprising two or more of the monolithic mirror arrays.

19. The solar energy system of claim 11, wherein the monolithic mirror array, the planar surface, and the receiver devices form a hermetically sealed enclosure.

20. The solar energy system of claim 11, wherein the plurality of receivers fit integrally into the apertures at the base of the concave surfaces.

21. The solar energy system of claim 11, further comprising a backpan fixedly mounted to the monolithic mirror array.

22. The solar energy system of claim 14, further comprising a backpan fixedly mounted to the monolithic mirror array via the integral attachment element.

23. A solar energy device comprising:
a monolithic mirror comprising:
a single piece of formable material having a first side and a second side;
a concave surface formed in the first side, wherein the concave surface is substantially parabolic in shape and has a base and wherein an aperture is located at the base;
a mirror coating deposited on at least a portion of the concave surface of the first side; and
an attachment element integral to the formable material.

24. The solar energy device of claim 23, further comprising:
a receiver device comprising a non-imaging rod and a photovoltaic cell;
a substantially transparent planar surface disposed on the first side of the monolithic mirror; and
a convex secondary mirror mounted to the planar surface, wherein the convex secondary mirror is located in a position defining a focal region at which light received by the concave surface is concentrated onto the photovoltaic cell.
